(19) United States
(12) Patent Application Publication
(10) Pub. No.: US 2004/0185624 A1
(43) Pub. Date: Sep. 23, 2004

(54) Semiconductor device and method for fabricating the same

(75) Inventors: Yasuyuki Tamura, Kawasaki (JP); Yoshihiro Sugiyama, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 10/765,894

(22) Filed: Jan. 29, 2004

(30) Foreign Application Priority Data
Feb. 10, 2003 (JP) 2003-031863

(51) Int. Cl. H01L 21/8234; H01L 21/336

(52) U.S. Cl. 438/275; 438/287

(57) ABSTRACT

The semiconductor device comprises a gate insulation film 23 formed on a first region 14 of a semiconductor substrate 10 and including a silicon oxide-based insulation film 18, a high dielectric constant film 20 formed on the silicon oxide-based insulation film 18, and an oxygen diffusion preventing film 22 formed on the high dielectric constant film 18 and having a lower oxygen diffusion coefficient than the high dielectric constant film 18; a gate electrode 24 formed on the first gate insulation film 23; a gate insulation film 25 formed on a second region 16 of the semiconductor substrate 10 and including the high dielectric constant film 20 and the oxygen diffusion preventing film 22 formed on the high dielectric constant film 20; and a gate electrode 24 formed on the gate insulation film 26.

### CROSS-REFERENCE TO RERATED APPLICATION

This application is based upon and claims priority of Japanese Patent Application No. 2003-031863, filed on Feb. 10, 2003, the contents being incorporated herein by reference.

### BACKGROUND OF THE INVENTION

The present invention relates to a semiconductor device mixedly including MOS structures having gate insulation films of different film thicknesses, materials, etc., and a method for fabricating the semiconductor device.

Recently the high speed operation, integration and hybridization of semiconductor devices, such as logic circuits, RAMs (Random Access Memory), EPROMs (Erasable Programmable Read Only Memory), LCDs (Liquid Crystal Display), etc., are rapidly going on. Resultantly, as the insulation films, such as the gate insulation films, the tunnel insulation films, etc. of the MOS (Metal Oxide Semiconductor) structures of such semiconductor devices, various insulation films are used in place of silicon oxide film, which has been conventionally used.

Insulation films of silicon oxide film have been so far used as the insulation films of the gate insulation films, tunnel insulation films, etc. of the MOS structures. However, as semiconductor devices are micronized, the gate insulation films and the tunnel insulation films are increasingly thinned. Consequently, a difficulty of increase of the gate leak current, etc. due to the tunnel current has become conspicuous. To solve such difficulty it is being studied to use as the gate insulation films, etc. insulation films of high dielectric constants (hereinafter called high-k insulation films) which are higher than the dielectric constant of silicon oxide film as the gate insulation films, etc., whereby the physical film thickness of the gate insulation films, etc. are made thick. As such high-k insulation film materials, hafnium oxide (HfO₂), halfnium alminate (HfAlO), zirconium oxide (ZrO₂) are recently noted because of characteristics of the high reaction free energy, the high band gap, etc. (refer to, e.g., E. P. Gusev et al., “Ultra high-K gate stacks for advanced CMOS devices,” International Electron Devices Meeting Technical Digest (2001), pp. 451-454, and W. Zhu et al., “HfO₂ and HfAlO for CMOS: Thermal Stability and Current Transport,” International Electron Devices Meeting Technical Digest (2001), pp. 463-466).

### SUMMARY OF THE INVENTION

An object of the present invention is to provide a semiconductor device mixedly including MOS structures having gate insulation films of different film thicknesses, materials, etc., which can use insulation films of high dielectric constants as the insulation films without deteriorating the element characteristics, and a method for fabricating the semiconductor device.

The inventors of the present application have confirmed cases that in MOS transistors having gate insulation films of the layer structure of a silicon oxide film and a high-k insulation film, leak current which is larger than that expected based on the film thicknesses, etc. of the silicon oxide film and the high-k insulation film (refer to Y. Tamura et al., “Electrical characteristics of SiO₂/High-k stacked gate insulator,” Extended Abstracts (The 49th Spring Meeting, 2002); The Japan Society of Applied Physics and Related Societies, No. 2, 28p-A-10, p. 820).

According to one aspect of the present invention, there is provided a semiconductor device comprising: a gate insulation film which is formed on a semiconductor substrate and includes a silicon oxide-based insulation film, a high dielectric constant film formed on the silicon oxide-based insulation film, and an oxygen diffusion preventing film formed on the high dielectric constant film and having a lower oxygen diffusion coefficient than the high dielectric constant film; and a gate electrode formed on the gate insulation film.

According to another aspect of the present invention, there is provided a semiconductor device comprising: a first gate insulation film formed on a first region of a semiconductor substrate and including a silicon oxide-based insulation film, a high dielectric constant film formed on the silicon oxide-based insulation film, and an oxygen diffusion preventing film formed on the high dielectric constant film and having a lower oxygen diffusion coefficient than the high dielectric constant film; a first gate electrode formed on the first gate insulation film; a second gate insulation film formed on a second region of the semiconductor substrate and including the high dielectric constant film and the oxygen diffusion preventing film formed on the high dielectric constant film; and a second gate electrode formed on the second gate insulation film.

According to further another aspect of the present invention, there is provided a semiconductor device comprising: a gate insulation film formed on a semiconductor substrate, and including a silicon oxide-based insulation film and a reduction-retardant high dielectric film formed on the silicon oxide-based insulation film; and a gate electrode formed on the gate insulation film.

According to further another aspect of the present invention, there is provided a semiconductor device comprising: a first gate insulation film formed on a first region of a semiconductor substrate and including a silicon oxide-based insulation film and a reduction-retardant high dielectric constant film formed on the silicon oxide-based insulation film; a first gate electrode formed on the first gate insulation film; a second gate insulation film formed on a second region of the semiconductor substrate and including the high dielectric film; and a second gate electrode formed on the second gate insulation film.

According to further another aspect of the present invention, there is provided a method for fabricating a semiconductor device comprising the steps of: forming a silicon oxide-based insulation film on a semiconductor substrate; forming a high dielectric constant film on the. silicon oxide-based insulation film; forming on the high dielectric constant film an oxygen diffusion preventing film having a lower oxygen diffusion coefficient than the high dielectric constant film; and forming a gate electrode on the oxygen diffusion preventing film.

According to further another aspect of the present invention, there is provided a method for fabricating a semiconductor device comprising the steps of: forming a silicon oxide-based insulation film on a semiconductor substrate in a first region; forming a high dielectric constant film on the silicon oxide-based insulation film in the first region and on the semiconductor substrate in a second region; forming an oxygen diffusion preventing film having a lower oxygen diffusion coefficient than the high dielectric constant film on the high dielectric constant film in the first region and on the high dielectric constant film in the second region; and forming a first gate electrode on the oxygen diffusion preventing film in the first region and a second gate electrode on the oxygen diffusion preventing film in the second region.

According to further another aspect of the present invention, there is provided a method for fabricating a semiconductor device comprising the steps of: forming a silicon oxide-based insulation film on a semiconductor substrate; forming a reduction-retardant high dielectric constant film on the silicon oxide insulation film; and forming a gate electrode on the high dielectric constant film.

According to further another aspect of the present invention, there is provided a method for fabricating a semiconductor device comprising the steps of: forming a silicon oxide-based insulation film on a semiconductor substrate in a first region; forming a reduction-retardant high dielectric constant film on the silicon oxide-based insulation film in the first region and on the semiconductor substrate in a second region; and forming a first gate electrode on the high dielectric constant film in the first region and a second gate electrode on the high dielectric constant film in the second region.

As described above, according to the present invention, on a semiconductor substrate, a gate insulation film is formed of a silicon oxide-based insulation film, a high dielectric constant film formed on the silicon oxide-based insulation film and an oxygen diffusion preventing film formed on the high dielectric constant film and having a lower oxygen diffusion coefficient than the high dielectric constant film; and a gate electrode is formed on the gate insulation film, whereby the reaction of reducing the silicon oxide-based insulation film can be suppressed, and generation of the gate leak current can be suppressed.

According to the present invention, on a first region of a semiconductor substrate a first gate insulation film is formed of a silicon oxide-based insulation film, a high dielectric constant film formed on the silicon oxide-based insulation film, and an oxygen diffusion preventing film formed on the high dielectric constant film and having a lower oxygen diffusion coefficient than the high dielectric constant film; a first gate electrode is formed on the first gate insulation film; on a second region of the semiconductor substrate a second gate insulation film is formed of the high dielectric constant film and the oxygen diffusion preventing film formed on the high dielectric constant film; a second gate electrode is formed on the second gate insulation film, whereby the reaction of reducing the silicon oxide-based insulation film in the first region can be suppressed, and generation of the gate leak current can be suppressed. Thus, even in cases that MOS structures the gate insulation films of which are different from each other in the film thickness, material, etc. are mixedly used, the high dielectric constant film can be used as the gate insulation films without deteriorating the element characteristics.

According to the present invention, on a semiconductor substrate, a gate insulation film is formed of a silicon oxide-based insulation film and a reduction-retardant high dielectric film formed on the silicon oxide-based insulation film; and a gate electrode is formed on the gate insulation film, whereby the reaction of reducing the silicon oxide-based insulation film can be suppressed, and generation of the gate leak current can be suppressed.

According to the present invention, on a first region of a semiconductor substrate, a first gate insulation film is formed of a silicon oxide-based insulation film and a reduction-retardant high dielectric constant film formed on the silicon oxide-based insulation film; a first gate electrode is formed on the first gate insulation film; on a second region of the semiconductor substrate, a second gate insulation film is formed of the high dielectric film; and a second gate electrode is formed on the second gate insulation film, whereby the reaction of reducing the silicon oxide-based insulation film in the first region can be suppressed, and generation of the gate leak current can be suppressed. Thus, even in cases that MOS structures the gate insulation films of which are different from each other in the film thickness, material, etc. are mixedly used, the high dielectric constant film can be used as the gate insulation films without deteriorating the element characteristics.

### BRIEF DESCRIPTION OF THE DRAWINGS

FIG. 1 is a sectional view of the semiconductor device according to a first embodiment of the present invention, which shows a structure thereof.

FIGS. 2A-2D are sectional views of the semiconductor device according to the first embodiment in the steps of the method for fabricating the same, which show the method (Part 1).

FIGS. 3A-3D are sectional views of the semiconductor device according to the first embodiment in the steps of the method for fabricating the same, which show the method (Part 2).

FIGS. 4A-4C are sectional views of the semiconductor device according to the first embodiment in the steps of the method for fabricating the same, which show the method (Part 3).

FIG. 5 is a sectional view of the semiconductor device according to a second embodiment of the present invention, which shows a structure thereof.

FIGS. 6A-6D are sectional views of the semiconductor device according to the second embodiment in the steps of the method for fabricating the same, which show the method (Part 1).

FIGS. 7A-7C is sectional views of the semiconductor device according to the second embodiment in the steps of the method for fabricating the same, which show the method (Part 2).

FIG. 8 is a graph of the measured results of the gate leak current vs. the gate voltage of the semiconductor device according to the present invention and the conventional semiconductor device.

FIGS. 9A-9C are sectional views of the semiconductor device including gate insulation films of different film thicknesses in the steps of the method for fabricating the same, which show the method (Part 1).

FIGS. 10A-10C are sectional views of the semiconductor device including gate insulation films of different film thicknesses in the steps of the method for fabricating the same, which show the method (Part 2).

### DETAILED DESCRIPTION OF THE INVENTION

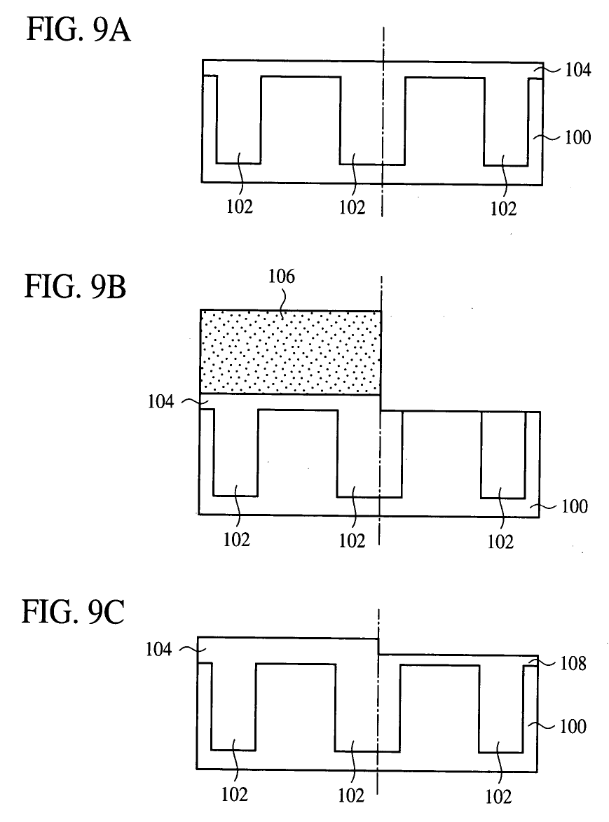

In LSI circuits, voltages applied to the elements, such as MOS transistors, etc. are not uniform; regions for high voltages to be applied to and regions for low voltages to be applied to are mixed. In such LSI circuits, the MOS transistors in the region for high voltages to be applied to have thick gate insulation film so as to suppress the gate leak current to ensure high reliability. On the other hand, the MOS transistors in the region for low voltages to be applied to have thin gate insulation film for high performance. When MOS transistors having such different gate insulation films are mixedly formed on a substrate, the gate insulation films are formed in the steps as exemplified in FIGS. 9A-9C.

First, a silicon substrate 100 with element regions defined by an element isolation insulation film 102 is thermally oxidized to thereby form a silicon oxide film 104 on the surface of the silicon substrate 100 (refer to FIG. 9A).

Next, a photoresist film 106 is formed on a high-voltage applied region, and then the silicon oxide film 104 in the low-voltage applied region is etched off (refer to FIG. 9B).

Then, the photoresist film 106 on the high-voltage applied region is removed, and then the silicon substrate 100 is again thermally oxidized to form a silicon oxide film 108 in the low-voltage applied region (refer to FIG. 9C). At this time, the silicon oxide film 104 in the high-voltage applied region is oxidized again to resultantly increase the film thickness.

Thus, a gate insulation film is formed of the thick silicon oxide film 104 in the high-voltage applied region of the silicon substrate 100, and a gate insulation film of the thin silicon oxide film 108 is formed in the low-voltage applied region.

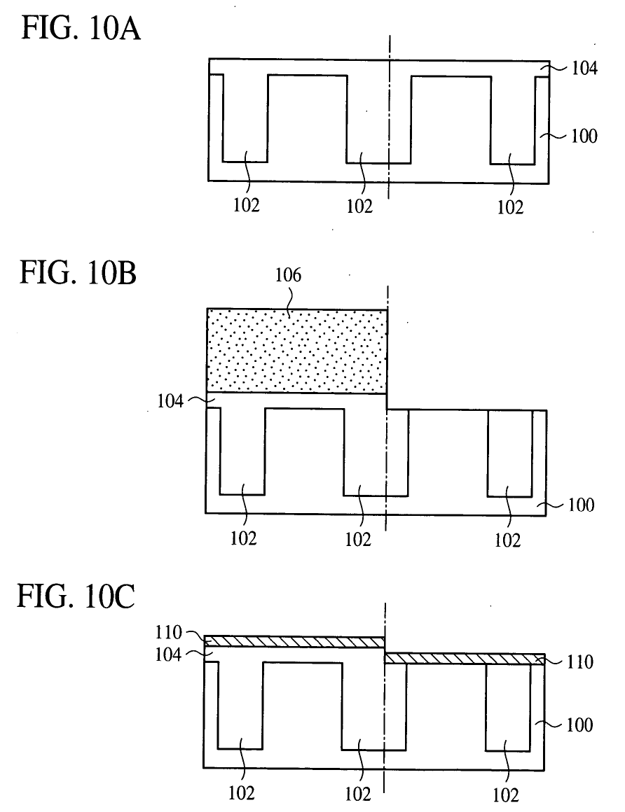

In a case where the gate insulation film in the low-voltage applied region is formed of a high-k insulation film in place of silicon oxide film, the gate insulation film is formed in the steps as exemplified in FIGS. 10A-10C.

First, a silicon substrate 100 with element regions defined by an element isolation insulation film is thermally oxidized to form a silicon oxide film 104 on the surface of the silicon substrate 100 (refer to FIG. 10A).

Then, a photoresist film 106 is formed on a high-voltage applied region, and then the silicon oxide film 104 in a low-voltage applied region is removed (refer to FIG. 10B).

Next, the photoresist film 106 on the high-voltage applied region is removed, and then a high-k insulation film 110 of a hafnium oxide film, zirconium oxide film or others is formed on the entire surface by CVD (Chemical Vapor Deposition) (refer to FIG. 10C).

A thick gate insulation film of a layer film of the silicon oxide film 104 and the high-k insulation film 110 is formed on the silicon substrate 100 in the high-voltage applied region, and a thin gate insulation film of the high-k insulation film 110 is formed on the silicon substrate 100 in the low-voltage applied region.

As described above, when different gate insulation films are formed in different region on one and the same substrate, a gate insulation film of the layer structure of a silicon oxide film and a high-k insulation film is often formed in a region. That is, as shown in FIG. 10C, when a high-k insulation film is used as a gate insulation film in a low-voltage applied region of an LSI circuit or others, a gate insulation film of the layer structure of a silicon oxide film formed by thermal oxidation and a high-k insulation film is formed in a high-voltage applied region.

[A First Embodiment]

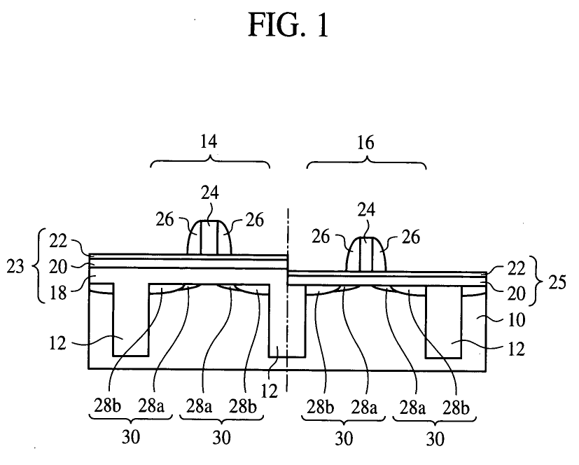

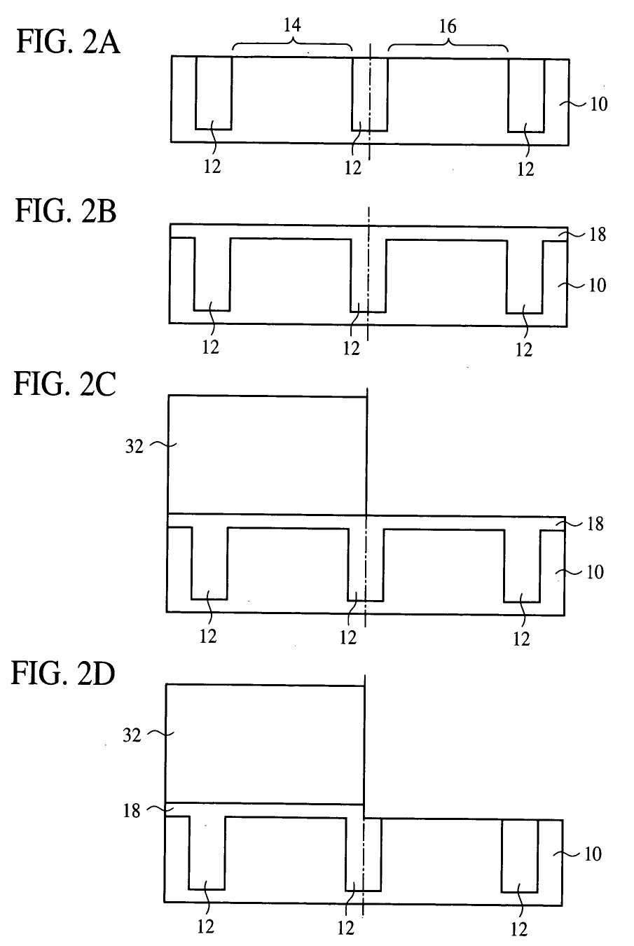

The semiconductor device and the method for fabricating the same according to a first embodiment of the present invention will be explained with reference to FIGS. 1, 2A-2D, 3A-3D and 4A-4C. FIG. 1 is a sectional view of the semiconductor device according to the present embodiment, which shows a structure thereof. FIGS. 2A-2D, 3A-3D and 4A-4C are sectional views of the semiconductor device according to the present embodiment in the steps of the method for fabricating the same, which show the method.

First, the structure of the semiconductor device according to the present embodiment will be explained with reference to FIG. 1.

A first element region 14 and a second element region 16 are defined on a silicon substrate 10 by an element isolation insulation film 12.

On the silicon substrate 10 in the first element region 14, a gate insulation film 23 of a silicon oxide film 18, a high-k film 20 of hafnium oxide film and an oxygen diffusion preventing film 22 of silicon nitride film are laid the latter on the former is formed.

On the silicon substrate 10 in the second element region 16, a gate insulation film 25 of the high-k film 20 of hafnium oxide film and the oxygen diffusion preventing film 22 of silicon nitride film laid the latter on the former is formed.

Gate electrodes 24 formed of a polysilicon film are formed on the oxygen diffusion preventing film 22 in the first element region 14 and in the second element region 16, respectively. A sidewall insulation film 26 is formed on the respective side wall of the gate electrodes 24.

Lightly doped diffused layers 28a are formed in the silicon substrate 10 in the first element region 14 and the second element region 16 formed by lightly implanting a dopant by self-alignment with the gate electrodes 24. Heavily doped diffused layers 28b are formed in the silicon substrate 10 in the first element region 14 and the second element region 16 formed by heavily implanting a dopant by self-alignment with the sidewall insulation films 26 and the gate electrodes 24. The lightly doped diffused layer 28a and the heavily doped diffused layer 28b form a source/drain diffused layer 30 of an LDD (Lightly Doped Drain) structure.

Thus, in the first element region 14, a high-voltage resistant transistor having the gate electrode 24, the source/drain diffused layer 30, and the gate insulation film 23, which includes the silicon oxide film 18 thick, is formed. In the second element region 16, a low-voltage operative transistor having the gate electrode 24, the source/drain diffused layer 30, and the gate insulation film 25, which does not include the silicon oxide film 18 thin, is formed.

The semiconductor device according to the present embodiment is characterized mainly in that on the layer film of the silicon oxide film 18 and the high-k film 20 of halfnium oxide film in the first element region 14, the oxygen diffusion preventing film 22 of silicon nitride film, whose oxygen diffusion coefficient is lower than the high-k film 20 is formed.

Conventionally in MOS transistors having gate electrodes of polysilicon film formed on the layer film of a silicon oxide film and a hafnium oxide film, the gate leak current is often larger than an expected value, deteriorating the transistor characteristics. This might be due to the following reaction of reducing the silicon oxide film. That is, in the conventional methods for fabricating semiconductor devices, after the layer film. of a silicon oxide film and a hafnium oxide film has been formed, the processing in a reducing atmosphere, as of forming a polysilicon film for forming gate electrodes, etc., is performed. In such processing in a reducing atmosphere, the silicon oxide film is reduced. Here, the high-k film, as of hafnium oxide film, zirconium oxide film or others, formed on the silicon oxide film, which is a good oxygen conductor, will accelerates the reaction of reducing the silicon oxide film. Resultantly, the insulation of the gate insulation film is lowered, and the gate leak current is increased.

In contrast to this, in the semiconductor device according to the present embodiment, the oxygen diffusion preventing film 22 of silicon nitride film, whose oxygen diffusion coefficient is lower than the high-k film 20 is formed on the high-k film 20 of hafnium oxide film. The presence of this oxygen diffusion preventing film 22 can suppress the reaction of reducing the silicon oxide film 18 formed under the high-k film 20 in the processing, etc. in a reducing atmosphere in fabrication steps. Thus, in the first element region 14, the insulation decrease of the gate insulation film 23 can be suppressed, and the deterioration of the transistor characteristics due to the increase of the gate leak current can be suppressed.

Next, the method for fabricating the semiconductor device according to the present embodiment will be explained with reference to FIGS. 2A-2D, 3A-3D and 4A-4C.

First, the element isolation insulation film 12 is formed of a silicon oxide film on the silicon substrate 10 by, e.g., the usual STI (Shallow Trench Isolation) to define the first element region 14 and the second element region 16 (refer to FIG. 2A).

Next, the silicon oxide film 18 of a 5.5 nm-thickness is formed on the surface of the silicon substrate 10 in the element regions by, e.g., thermal oxidation (refer to FIG. 2B).

Then, a photoresist film 32 is formed by photolithography, covering the silicon oxide film 18 in the first element region 14 and exposing the silicon oxide film 18 in the second element region 16 (refer to FIG. 2C).

Then, with the photoresist film 32 as the mask, the silicon oxide film 18 is etched by using, e.g., hydrofluoric acid to expose the surface of the silicon substrate 10 in the second element region 16 (refer to FIG. 2D).

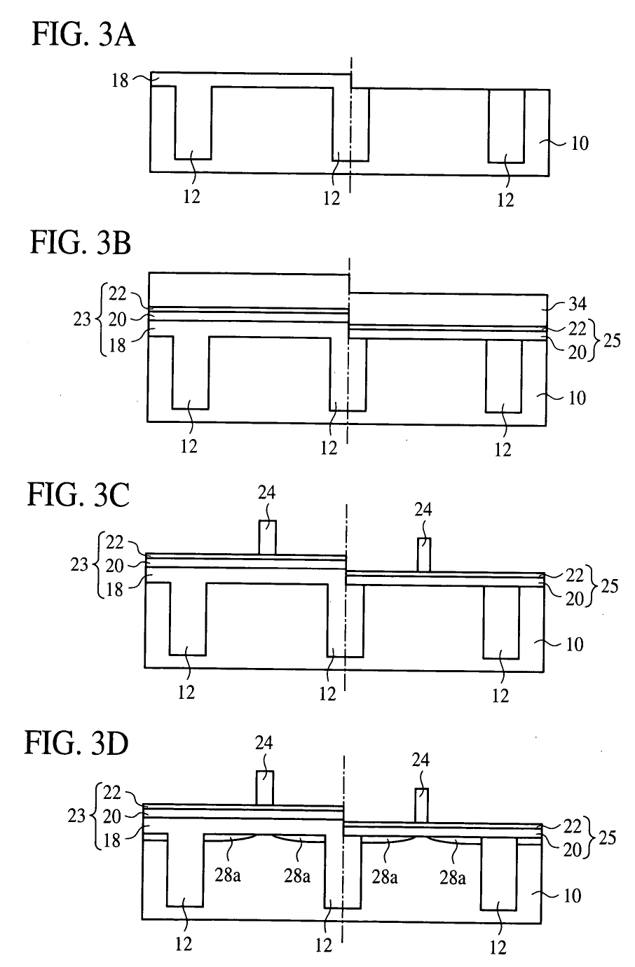

After the etching of the silicon oxide film 18 is completed, the photoresist film 32 on the silicon oxide film 18 in the first element region 14 is removed, and the silicon substrate 10 is cleaned (refer to FIG. 3A).

Then, the high-k film 20 of a 3 nm-thickness hafnium oxide film is formed on the entire surface by, e.g., CVD. Conditions for forming the high-k film 20 of the hafnium oxide film are, e.g., tetra(tertiary butoxy)hafnium (Hf(O-t-Bu)₄) and oxygen gas as the raw material gases, and a 500° C. substrate temperature.

Then, the oxygen diffusion preventing film 22 of a 1 nm-thickness silicon nitride film is formed on the high-k film 20 by, e.g., CVD. Conditions for forming the oxygen diffusion preventing film 22 of the silicon nitride film are, e.g., SiH₂Cl₂ gas and NH₃ gas as the raw material gases and a 600° C. substrate temperature.

Thus, the gate insulation film 23 is formed of the silicon oxide film 18, the high-k film 20 of the hafnium oxide film and the oxygen diffusion preventing film 22 of the silicon nitride film laid the latter on the former on the silicon substrate 10 in the first element region 14, and the gate insulation film 25 of the high-k film 20 of the hafnium oxide film and the oxygen diffusion preventing film 22 of the silicon nitride film laid the latter on the former is formed on the silicon substrate 10 in the second element region 16.

Then, the polysilicon film 34 of a 150 nm-thickness is formed on the oxygen diffusion preventing film 22 by, e.g., CVD (refer to FIG. 3B).

The polysiliocn film 34 is formed generally in a reducing atmosphere. In the method for fabricating the semiconductor device according to the present embodiment, before the step of forming the polysilicon film 34, the oxygen diffusion preventing film 22 of silicon nitride film whose oxygen diffusion coefficient is lower than the high-k film 20 is formed on the high-k film 20 of the hafnium oxide film which is known as a good oxygen conductor. Accordingly, when the polysilicon film 34 is formed in a reducing atmosphere, the reaction of reducing the silicon oxide film 18 formed below the high-k film 20 in the first element region 14 is suppressed. Thus, the insulation decrease of the gate insulation film 23 due to the reduction of the silicon oxide film 18 can be suppressed, whereby the generation of the gate leak current in the first element region 14 can be suppressed.

Next, the polysilicon film 34 is patterned by lithography and etching to form the gate electrodes 24 of the polysilicon film 34 on the oxygen diffusion preventing film 22 respectively in the first element region 14 and in the second element region 16 (refer to FIG. 3C).

Then, with the gate electrodes 24 as the mask, dopant ions are implanted to form the lightly doped diffused layer 28a of the LDD structure in the silicon substrate 10 by self-alignment with the gate electrodes 24 (refer to FIG. 3D).

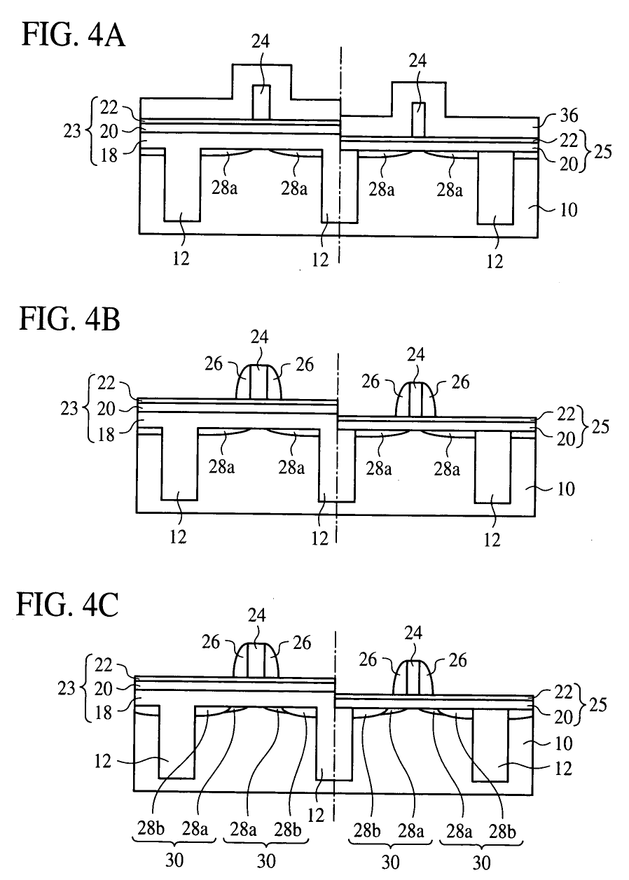

Next, the silicon oxide film 36 is formed on the entire surface by, e.g., CVD (refer to FIG. 4A). The formed silicon oxide film 36 is anisotropically etched to form the sidewall insulation film 26 on the side walls of the gate electrodes 24 (refer to FIG. 4B).

Then, with the gate electrodes 24 and the sidewall insulation film 26 as the mask, dopant ions are implanted to form the heavily doped diffused layer 28b of the LDD structure (refer to FIG. 4C). Thus, the source/drain diffused layer 30 of the LDD structure is formed of the lightly doped diffused layer 28a and the heavily doped diffused layer 28b.

Thus, the semiconductor device according to the present embodiment shown in FIG. 1 is fabricated.

As described above, according to the present embodiment, on the layer film of the silicon oxide film 18 and the high-k film 20 formed of the hafnium oxide film, the oxygen diffusion preventing film 22 whose oxygen diffusion coefficient is lower than that of the high-k film 20 is formed, whereby in the processing in a reducing atmosphere, the reaction of reducing the silicon oxide film 18 formed below the high-k film 20 in the first element region 14 can be suppressed. Resultantly, the insulation decrease of the gate insulation film 23 due to the reduction of the silicon oxide film 18 can be suppressed, whereby deterioration of the transistor characteristics due to increase of the leak current in the first element region 14 can be suppressed. Consequently, the semiconductor device including the MOS structures having the gate insulation films 23, 25 different from each other can have higher performance and higher reliability.

[A Second Embodiment]

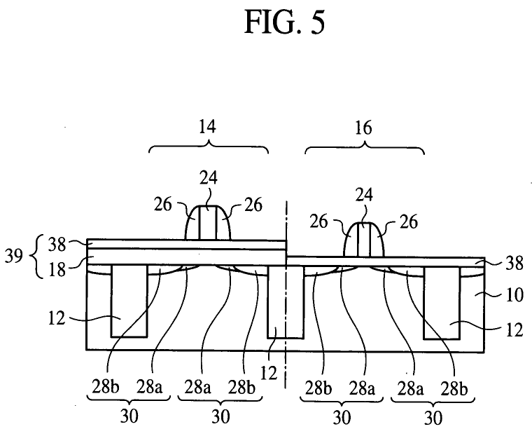

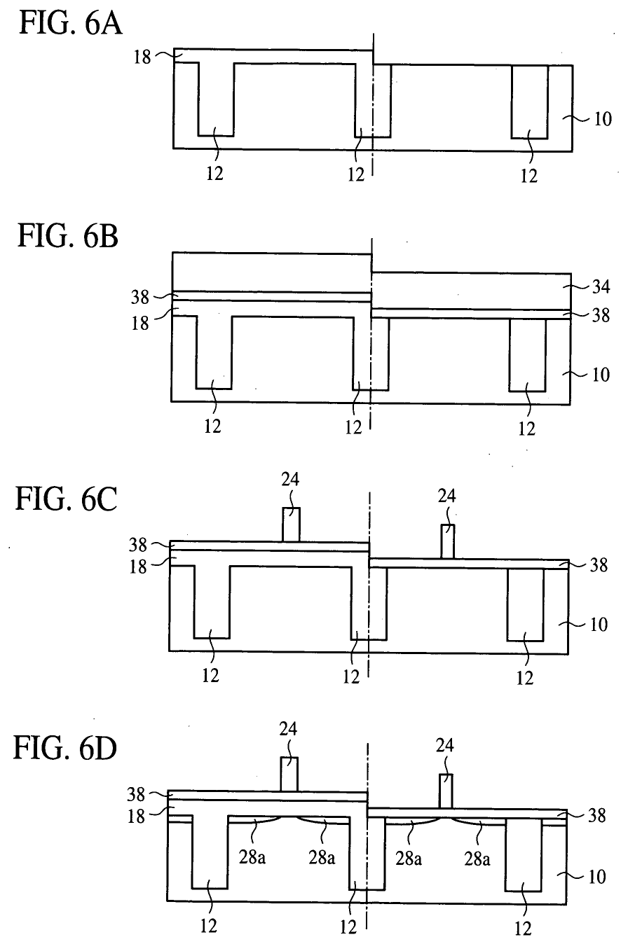

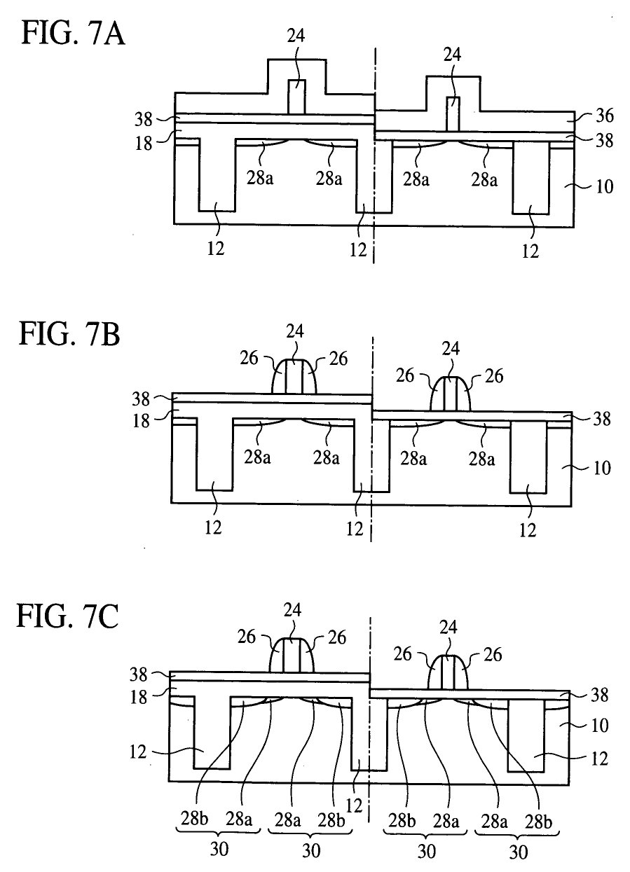

The semiconductor device and the method for fabricating the same according to a second embodiment of the present invention will be explained with reference to FIGS. 5, 6A-6D and 7A-7C. FIG. 5 is a sectional view of the semiconductor device according to the present embodiment, which shows a structure thereof. FIGS. 6A-6D and 7A-7C are sectional views of the semiconductor device according to the present embodiment in the steps of the method for fabricating the same, which show the method. The same members of the present embodiment as those of the semiconductor device and the method for fabricating the same according to the first embodiment are represented by the same reference numbers not to repeat or to simplify their explanation.

First, the structure of the semiconductor device according to the present embodiment will be explained with reference to FIG. 5.

A first element region 14 and a second element region 16 are defined by an element isolation insulation film 12 on a silicon substrate 10.

On the silicon substrate 10 in the first element region 14, a gate insulation film 39 formed of a silicon oxide film 18 and a high-k film 38 of a hafnium aluminate (Hf_{0.5}Al_{0.5}O₂) film is formed.

On the silicon substrate 10 in the second element region 16, the high-k film 38 of the hafnium aluminate film is formed as the gate insulation film.

Gate electrodes 24 are formed on the high-k film 38 respectively in the first element region 14 and in the second element region 16. A sidewall insulation film 26 is formed on the side walls of the gate electrodes 24.

Lightly doped diffused layers 28a are formed in the silicon substrate 10 by lightly implanting a dopant by self-alignment with the gate electrodes 24. Heavily doped diffused layers 28b are formed in the silicon substrate 10 by heavily implanting a dopant by self-alignment with the sidewall insulation film 26 and the gate electrodes 24. The lightly doped diffused layer 28a and the heavily doped diffused layer 28b form a source/drain diffused layer 30 of an LDD structure.

Thus, in the first element region 14, a high voltage resistant transistor including the gate electrode 24, the source/drain diffused layer 30 and the gate insulation film 39 which includes the silicon oxide film 18 thick, is formed. In the second element region 16, a low voltage operative transistor including the gate electrode 24, the source/drain diffused layer 30 and the gate insulation film formed of the high-k film 38 alone thin, is formed.

The semiconductor device according to the present embodiment is characterized mainly in that the high-k film 38 of hafnium aluminate film having a prescribed alumina content ratio is formed on the silicon oxide film 18 in the first element region 14.

Hafnium aluminate film has a characteristic that hafnium aluminate having a high alumina content ratio is not easily reduced even by the exposure to a reducing atmosphere. The presence of the high-k film 38 of the hafnium aluminate film of such reduction retardation can suppress the reaction of reducing the silicon oxide film 18 formed below the high-k film 38 in the processing in reducing atmospheres of fabrication steps. Thus, the insulation decrease of the gate insulation film 39 in the first element region 14 can be suppressed, and deterioration of the transistor characteristics due to increase of the gate leak current can be suppressed. To sufficiently suppress the reaction of reducing the silicon oxide film 18 it is preferable that the alumina content ratio of the hafnium aluminate film used as the high-k film 38 is, e.g., above 50% including 50%.

Then, the method for fabricating the semiconductor device according to the present embodiment will be explained with reference to FIGS. 6A-6D and 7A-7C.

First, in the same way as in the first embodiment, the silicon oxide film 18 is formed on the silicon substrate 10, and then the surface of the silicon substrate 10 in the second element region 16 is exposed (refer to FIG. 6A).

Next, the high-k film 38 of a 2 nm-thickness hafnium aluminate film is formed on the entire surface by, e.g., CVD. Conditions for forming the high-k film 38 of the halfnium aluminate film are, e.g., tetra(tertiary butoxy)hafnium (Hf (O-t-Bu) ₄) and tri(tertiary butyl)aluminium (Al(t-Bu) ₃) and oxygen gas as the raw material gases, and a 500° C. substrate temperature. At this time, the flow rate of the raw material gases is adjusted to form the high-k film 38 of a halfnium aluminate film containing alumina by, e.g., above 50% including 50%.

Then, the polysilicon film 22 of a 150 nm-thickness is formed on the high-k film 38 by, e.g., CVD (refer to FIG. 6C).

In the method for fabricating the semiconductor device according to the present embodiment, the high-k film 38 of the halfnium aluminate film is formed on the silicon oxide film 18 before the step of forming the polysilicon film 34 in a reducing atmosphere. The hafnium aluminate film whose alumina content ratio is, e.g., above 50% including 50% is not readily reduced even by the exposure to a reducing atmosphere. In the forming the polysilicon film 34 in a reducing atmosphere, the reaction of reducing the silicon oxide film 18 formed below the high-k film 38 of the hafnium aluminate film in the first element region 14 can be suppressed. Thus, the insulation decrease of the gate insulation film 39 due to the reduction of the silicon oxide film 18 can be suppressed, and the generation of the leak current in the first element region 14 can be suppressed.

Next, the polysilicon film 34 is patterned by lithography and etching to form the gate electrodes 24 of the polysilicon film 34 on the high-k film 38 respectively in the first element region 14 and in the second element region 16 (Refer to FIG. 6C).

Next, with the gate electrodes 24 as the mask, dopant ions are implanted to form the lightly doped diffused layer 28a of the LDD structure in the silicon substrate 10 by self-alignment with the gate electrodes 24 (refer to FIG. 6D).

Next, the silicon oxide film 36 is formed on the entire surface by, e.g., CVD and is anisotropically etched to form the sidewall insulation film 26 on the side walls of the gate electrodes 24 (refer to FIGS. 7A and 7B).

Then, with the gate electrodes 24 and the sidewall insulation film 26 as the mask, dopant ions are implanted to form the heavily doped diffused layer 28b of the LDD structure (refer to FIG. 7C). Thus, the source/drain diffused layer 30 of the LDD structure is formed of the lightly doped diffused layer 28a and the heavily doped diffused layer 28b.

Thus, the semiconductor device according to the present embodiment shown in FIG. 5 is fabricated.

As described above, according to the present embodiment, the high-k film 38 of hafnium aluminate film is formed on the silicon oxide film 18, whereby the reaction of reducing the silicon oxide film 18 formed below the high-k film 38 of hafnium aluminate film in the first element region 14 in the processing in a reducing atmosphere can be suppressed. Thus, the insulation decrease of the gate insulation film 39 due to the reduction of the silicon oxide film 18 can be suppressed, whereby deterioration of the transistor characteristics due to increase of the gate leak current in the first element region can be suppressed. Resultantly, semiconductor devices mixedly including MOS structures having different gate insulation films can have higher performance and higher reliability.

[Evaluation Result]

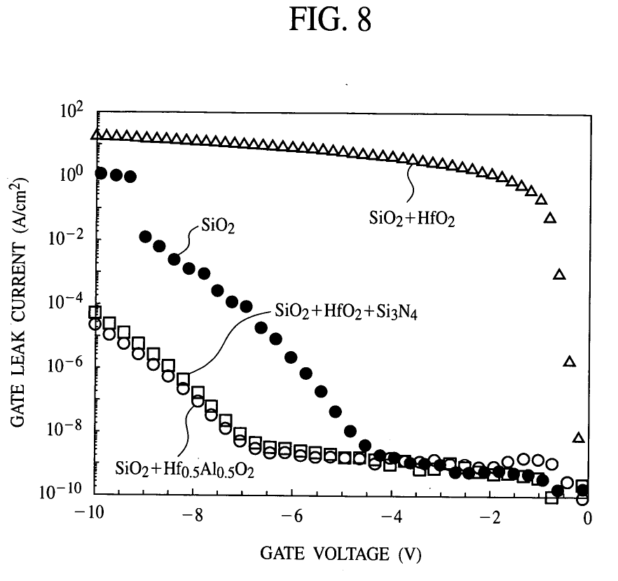

The effect of decreasing the gate leak current of the semiconductor device according to the present invention will be explained with reference to FIG. 8. FIG. 8 is a graph of the gate leak current measured with respect to the gate voltage of the semiconductor device according to the present invention and the conventional semiconductor device. The gate leak current was measured on Examples 1 to 3 and Controls 1 and 2 which will be described below.

Example 1 is an n type MOS transistor including a gate electrode formed of a polysilicon film on a silicon substrate with the layer film of a 5.5 nm-thickness silicon oxide film, a 3 nm-thickness hafnium oxide film and a 1 nm-thickness silicon nitride film formed therebetween. The measured result of Example 1 is plotted by □ in the graph.

Example 2 is an n type MOS transistor including a gate electrode of a polysiliocn film formed on a silicon substrate with the layer film of a 5.5 nm-thickness silicon oxide film and a 3 nm-thickness hafnium aluminate film formed therebetween. The composition of the hafnium aluminate film was Hf_{0.5}Al_{0.5}O₂. The measured result of Example 2 is plotted by ◯ in the graph.

Control 1 is an n type MOS transistor including a gate electrode formed of a polysilicon film on a silicon substrate with a 5.5 nm-thickness silicon oxide film formed therebetween. The measured result of Control 1 is plotted by ● in the graph.

Control 2 is an n type MOS transistor including a gate electrode formed of a polysilicon film on a silicon substrate with a 5.5 nm-thickness silicon oxide film and a 3 nm-thickness hafnium oxide film. The measured result of Control 2 is plotted by Δ in the graph.

The measured results of Controls 1 and 2 show that in the case that the hafnium oxide film is simply formed on the silicon oxide film, the gate leak current is much increased in comparison with the gate leak current in the case that no hafnium oxide film is formed on the silicon oxide film. This might be due to that the hafnium oxide film, which is a good oxygen conductor, accelerates the reduction of the silicon oxide film formed below the hafnium oxide film in the processing in a reducing atmosphere to thereby decrease the insulation of the gate insulation film.

On the other hand, in comparison with Controls 1 and 2, the gate leak current is sufficiently decreased both in Example 1 where the silicon nitride film is formed on the layer film of the silicon oxide film and the hafnium oxide film, and in Example 2 where the hafnium aluminate film is formed on the silicon oxide film.

Based on the above-described measured results, it has been confirmed that the semiconductor device according to the present invention can sufficiently decrease the gate leak current.

[Modified Embodiments]

The present invention is not limited to the above-described embodiments and can cover other various modifications.

For example, in the above-described embodiments, the thick gate insulation film is formed in the first element region 14 to which high voltages are applied to, and the thin gate insulation film is formed in the second element region 16 to which low voltages are applied to. However, the present invention is applicable to cases where gate insulation films of different film thicknesses, different materials, etc. are formed in different regions on one and the same semiconductor substrate.

In the first embodiment, the high-k film 20 is formed of hafnium oxide film but is not essentially formed of hafnium oxide film. The high-k film 20 can be formed of, e.g., zirconium oxide film or another film, which contains at least Hf or Zr and has a higher dielectric constant than silicon oxide film other than hafnium oxide film.

In the first embodiment, the oxygen diffusion preventing film 22 whose oxygen diffusion coefficient is lower than the high-k film 20 is silicon nitride film but is not essentially silicon nitride film. The oxygen diffusion preventing film 22 can be, e.g., alumina film, aluminum silicate film, hafnium aluminate film, hafnium silicate film or others other than silicon nitride film.

In the second embodiment, the high-k film 38 is hafnium aluminate film but can be film other than hafnium aluminate film as long as the film is reduction-retardant. The high-k film 38 can be, e.g., alumina film, aluminum silicate film, hafnium silicate film or others other than hafnium aluminate film.

In the above-described embodiment, the silicon oxide film 18 is formed by thermal oxidation but is not essentially formed by thermal oxidation. The silicon oxide film 18 is formed by, e.g., CVD or others.

In the above-described embodiments, the silicon oxide film 18 is formed on the silicon substrate 10 in the first element region. However, in place of the silicon oxide film 18, a silicon oxide-based insulation film with another element, such as nitrogen or others, introduced in silicon oxide, e.g., silicon oxynitride film or others, can be formed on the silicon substrate 10 in the first element region 14.

In the above-described embodiments, the gate electrodes 24 are formed of polysilicon film. However, the material and the structure of the gate electrodes 24 are not limited to the above. For example, a metal silicide is laid on a polysilicon film to thereby form the gate electrodes 24 of the polycide structure. A metal film is laid on a polysilicon film to thereby form the gate electrodes 24 of the polymetal structure. In place of the polysilicon film, a metal film of titanium nitride, tantalum nitride or others is formed on the gate insulation film to thereby form the gate electrodes 24 in metal gates.

In the above-described embodiments, the same gate electrodes 24 are formed in the first element region 14 and the second element region 16. However, gate electrodes which are different from each other in the material, structure, etc. may be formed in the first element region and the second element region.

What is claimed is:

1. A semiconductor device comprising:
a gate insulation film which is formed on a semiconductor substrate and includes a silicon oxide-based insulation film, a high dielectric constant film formed on the silicon oxide-based insulation film, and an oxygen diffusion preventing film formed on the high dielectric constant film and having a lower oxygen diffusion coefficient than the high dielectric constant film; and
a gate electrode formed on the gate insulation film.

2. A semiconductor device comprising:
a first gate insulation film formed on a first region of a semiconductor substrate and including a silicon oxide-based insulation film, a high dielectric constant film formed on the silicon oxide-based insulation film, and an oxygen diffusion preventing film formed on the high dielectric constant film and having a lower oxygen diffusion coefficient than the high dielectric constant film;
a first gate electrode formed on the first gate insulation film;
a second gate insulation film formed on a second region of the semiconductor substrate and including the high dielectric constant film and the oxygen diffusion preventing film formed on the high dielectric constant film; and
a second gate electrode formed on the second gate insulation film.

3. A semiconductor device according to claim 1, wherein
the high dielectric constant film is a hafnium oxide film or a zirconium oxide film.

4. A semiconductor device according to claim 2, wherein
the high dielectric constant film is a hafnium oxide film or a zirconium oxide film.

5. A semiconductor device according to claim 1, wherein
the oxygen diffusion preventing film is a silicon nitride film, an alumina film, an aluminum silicate film, a hafnium aluminate film or a hafnium silicate film.

6. A semiconductor device comprising:
a gate insulation film formed on a semiconductor substrate, and including a silicon oxide-based insulation film and a reduction-retardant high dielectric film formed on the silicon oxide-based insulation film; and
a gate electrode formed on the gate insulation film.

7. A semiconductor device comprising:
a first gate insulation film formed on a first region of a semiconductor substrate and including a silicon oxide-based insulation film and a reduction-retardant high dielectric constant film formed on the silicon oxide-based insulation film;
a first gate electrode formed on the first gate insulation film;
a second gate insulation film formed on a second region of the semiconductor substrate and including the high dielectric film; and
a second gate electrode formed on the second gate insulation film.

8. A semiconductor device according to claim 6, wherein
the high dielectric film is a hafnium aluminate film.

9. A semiconductor device according to claim 7, wherein
the high dielectric film is a hafnium aluminate film.

10. A semiconductor device according to claim 8, wherein
an alumina content ratio of the hafnium aluminate film is above 50% including 50%.

11. A semiconductor device according to claim 9, wherein
an alumina content ratio of the hafnium aluminate film is above 50% including 50%.

12. A method for fabricating a semiconductor device comprising the steps of:
forming a silicon oxide-based insulation film on a semiconductor substrate;
forming a high dielectric constant film on the silicon oxide-based insulation film;
forming on the high dielectric constant film an oxygen diffusion preventing film having a lower oxygen diffusion coefficient than the high dielectric constant film; and
forming a gate electrode on the oxygen diffusion preventing film.

13. A method for fabricating a semiconductor device comprising the steps of:
forming a silicon oxide-based insulation film on a semiconductor substrate in a first region;
forming a high dielectric constant film on the silicon oxide-based insulation film in the first region and on the semiconductor substrate in a second region;
forming an oxygen diffusion preventing film having a lower oxygen diffusion coefficient than the high dielectric constant film on the high dielectric constant film in the first region and on the high dielectric constant film in the second region; and
forming a first gate electrode on the oxygen diffusion preventing film in the first region and a second gate electrode on the oxygen diffusion preventing film in the second region.

14. A method for fabricating a semiconductor device according to claim 12, wherein
in the step of forming the high dielectric constant film, the high dielectric constant film is formed of a hafnium oxide film or a zirconium oxide film.

15. A method for fabricating a semiconductor device according to claim 13, wherein
in the step of forming the high dielectric constant film, the high dielectric constant film is formed of a hafnium oxide film or a zirconium oxide film.

16. A method for fabricating a semiconductor device according to claim 12, wherein
in the step of forming the oxygen diffusion preventing film, the oxygen diffusion preventing film is formed of a silicon nitride film, an alumina film, an aluminum silicate film, a hafnium aluminate film or a hafnium silicate film.

17. A method for fabricating a semiconductor device comprising the steps of:
forming a silicon oxide-based insulation film on a semiconductor substrate;
forming a reduction-retardant high dielectric constant film on the silicon oxide insulation film; and
forming a gate electrode on the high dielectric constant film.

18. A method for fabricating a semiconductor device comprising the steps of:
forming a silicon oxide-based insulation film on a semiconductor substrate in a first region;
forming a reduction-retardant high dielectric constant film on the silicon oxide-based insulation film in the first region and on the semiconductor substrate in a second region; and
forming a first gate electrode on the high dielectric constant film in the first region and a second gate electrode on the high dielectric constant film in the second region.

19. A method for fabricating a semiconductor device according to claim 17, wherein
in the step of forming the high dielectric constant film, the high dielectric constant film is formed of a hafnium aluminate film.

20. A method for fabricating a semiconductor device according to claim 18, wherein
in the step of forming the high dielectric constant film, the high dielectric constant film is formed of a hafnium aluminate film.

21. A method for fabricating a semiconductor device according to claim 19, wherein
an alumina content ratio of the hafnium aluminate film is above 50% including 50%.

22. A method for fabricating a semiconductor device according to claim 20, wherein
an alumina content ratio of the hafnium aluminate film is above 50% including 50%.

23. A method for fabricating a semiconductor device according to claim 12, wherein
the step of forming the gate electrode includes the step of forming a conducting film in a reducing atmosphere and the step of patterning the conducting film into the gate electrode.
